(19) United States
(12) Patent Application Publication
(10) Pub. No.: US 2024/0395879 A1
(43) Pub. Date: Nov. 28, 2024

(54) CONTACT INTEGRATION IN COMPLEMENTARY FIELD EFFECT TRANSISTOR (CFET) DEVICES

(71) Applicant: Applied Materials, Inc., Santa Clara, CA (US)

(72) Inventors: San-Kuei LIN, Cupertino, CA (US); Pradeep K. SUBRAHMANYAN, Santa Clara, CA (US)

(21) Appl. No.: 18/651,326

(22) Filed: Apr. 30, 2024

Related U.S. Application Data
(60) Provisional application No. 63/468,646, filed on May 24, 2023.

(51) Int. Cl. H01L 29/417; H01L 21/822; H01L 21/8238; H01L 23/522; H01L 23/528; H01L 27/06; H01L 27/092; H01L 29/08; H01L 29/49

(52) U.S. Cl. CPC H01L 29/41725; H01L 21/8221; H01L 21/823814; H01L 21/823871; H01L 23/5226; H01L 23/5283; H01L 27/0688; H01L 27/0922; H01L 29/0847; H01L 29/495

(57) ABSTRACT

A semiconductor structure includes a first common metal gate, a second common metal gate, a bottom field effect transistor (FET) module, the bottom FET module including a pair of bottom common source/drain (S/D) contacts electrically connected to each other through the first common metal gate in a first direction via first bottom S/D epitaxial (epi) regions, and through the second common metal gate in the first direction, and a top FET module stacked on the bottom FET module in a second direction that is orthogonal to the first direction, the top FET module including a top common S/D contact, a first top S/D contact electrically connected to the top common S/D contact through the first common metal gate in the first direction, and a second top S/D contact electrically connected to the top common S/D contact through the second common metal gate in the first direction.

### CROSS-REFERENCE TO RELATED APPLICATIONS

This application claims priority to U.S. Provisional Application Ser. No. 63/468,646 filed May 24, 2023, which is herein incorporated by reference in its entirety.

### BACKGROUND

### Field

Embodiments described herein generally relate to semiconductor device fabrication, and more particularly, to contact integration in complementary field effect transistor (CFET) devices.

### Description of the Related Art

To continue scaling beyond the physical limit of planar metal oxide semiconductor field effect transistor (MOSFET), three-dimensional FinFET, stacked nanosheet gate-all-around FET (GAA FETs), and complementary FET (CFET) have been proposed. In a CFET architecture, n- and p-devices are stacked on top of each other vertically, eliminating the n-p spacing from the standard cell height. In the currently proposed architectures, an n-FET and a p-FET vertically stacked in a single row are controlled by a common gate that results in device footprint reduction but routing of interconnect through a metal layer is still required. Thus, improvement in a CFET architecture further reducing device footprint and total interconnect metal length to reduce parasitic resistance is needed.

### SUMMARY

Embodiments of the present disclosure provide a semiconductor structure forming a complementary field-effect transistor (CFET). The semiconductor structure includes a first common metal gate, a second common metal gate, a bottom field effect transistor (FET) module, the bottom FET module including a pair of bottom common source/drain (S/D) contacts electrically connected to each other through the first common metal gate in a first direction via first bottom S/D epitaxial (epi) regions, and through the second common metal gate in the first direction via second bottom S/D epi regions, and a top FET module stacked on the bottom FET module in a second direction that is orthogonal to the first direction, the top FET module including a top common S/D contact, a first top S/D contact electrically connected to the top common S/D contact through the first common metal gate in the first direction via first top S/D epi regions, and a second top S/D contact electrically connected to the top common S/D contact through the second common metal gate in the first direction via second top S/D epi regions.

Embodiments of the present disclosure provide a method of forming a complementary field-effect transistor (CFET). The method includes performing a top contact trench patterning process to form a first top trench into a first front top S/D epi region, a second top trench into a second front top S/D epi region, and a third top trench into a first back top S/D epi region and a second back top S/D epi region, wherein the first front top S/D epi region and the first back top S/D epi region are electrically connected through a first common metal gate, and the second front top S/D epi region and the second back top S/D epi region are electrically connected through a second common metal gate, performing a top contact via patterning process to form a first via through the first front top S/D epi region and into a first front bottom S/D epi region, and a second via adjacent to the second front top S/D epi region and a second front bottom S/D epi region, wherein the first front bottom S/D epi region and a first back bottom S/D epi region are electrically connected through the first common metal gate, and the second front bottom S/D epi region and a second back bottom S/D epi region are electrically connected through the second common metal gate, performing a top metal fill process to form a first top S/D contact within the first top trench, a second top S/D contact within the second top trench, a top common S/D contact within the third top trench, a first via contact within the first via, and a second via contact within the second via, performing a bottom contact trench patterning process to form a first bottom trench into the first bottom front S/D epi region and the second bottom front S/D epi region and a second bottom trench into the first bottom back S/D epi region and the second bottom back S/D epi region, and performing a bottom metal fill process, to form a common bottom S/D contact within each of the first bottom trench and the second bottom trench.

Embodiments of the present disclosure provide a method of forming a complementary field-effect transistor (CFET). The method includes performing a top contact trench patterning process to form a first top trench into a first front top S/D epi region, a second top trench into a second front top S/D epi region, and a third top trench into a first back top S/D epi region and a second back top S/D epi region, wherein the first front top S/D epi region and the first back top S/D epi region are electrically connected through a first common metal gate, and the second front top S/D epi region and the second back top S/D epi region are electrically connected through a second common metal gate, performing a top contact via patterning process to form a first via adjacent to the first front top S/D epi region and a first front bottom S/D epi region, and a second via adjacent to the second front top S/D epi region and a second front bottom S/D epi region, wherein the first front bottom S/D epi region and a first back bottom S/D epi region are electrically connected through the first common metal gate, and the second front bottom S/D epi region and a second back bottom S/D epi region are electrically connected through the second common metal gate, performing a top metal fill process to form a first top S/D contact within the first top trench, a second top S/D contact within the second top trench, a top common S/D contact within the third top trench, a first via contact within the first via, and a second via contact within the second via, performing a bottom contact trench patterning process to form a first bottom trench into the first bottom front S/D epi region and the second bottom front S/D epi region and a second bottom trench into the first bottom back S/D epi region and the second bottom back S/D epi region, and performing a bottom metal fill process, to form a common bottom S/D contact within each of the first bottom trench and the second bottom trench.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIGS. 2A and 2B are isometric views of a portion of a semiconductor structure 200 that may form a complementary field-effect transistor (CFET) in a double-cell-height design, according to one or more embodiments of the present disclosure. In FIG. 2B, the semiconductor structure 200 beneath top metal layers is shown. FIG. 2C illustrates an exemplary NAND gate circuit that correspond to the portion of the semiconductor structures 200 shown in FIG. 2A.

FIG. 3 depicts a process flow diagram of a method of forming cell transistors in a semiconductor structure according to one embodiment.

FIGS. 4A, 4A′, 4B, 4B′, 4C, 4C′, 4D, 4D′, 4E, 4E′, 4F, 4F′, 4G, 4G′, 4H, and 4H′ are isometric views of a portion of a semiconductor structure corresponding to various states of the method of FIG. 3.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide double-cell-height structures of complementary FET (CFET) devices. In a conventional CFET architecture, an n-FET device and a p-FET device stacked vertically in a single row may be controlled by a common gate that is connected to a metal layer (referred to as a single-cell-height structure). In a double-cell-height structure, two row of stacks of an n-FET and a p-FET are interconnected and controlled by two common gates. The double-cell-height structure effectively reduces routing congestion and minimizes routing complexity of CFET. Resulting shorter interconnect length lowers parasitic resistance of a CFET device.

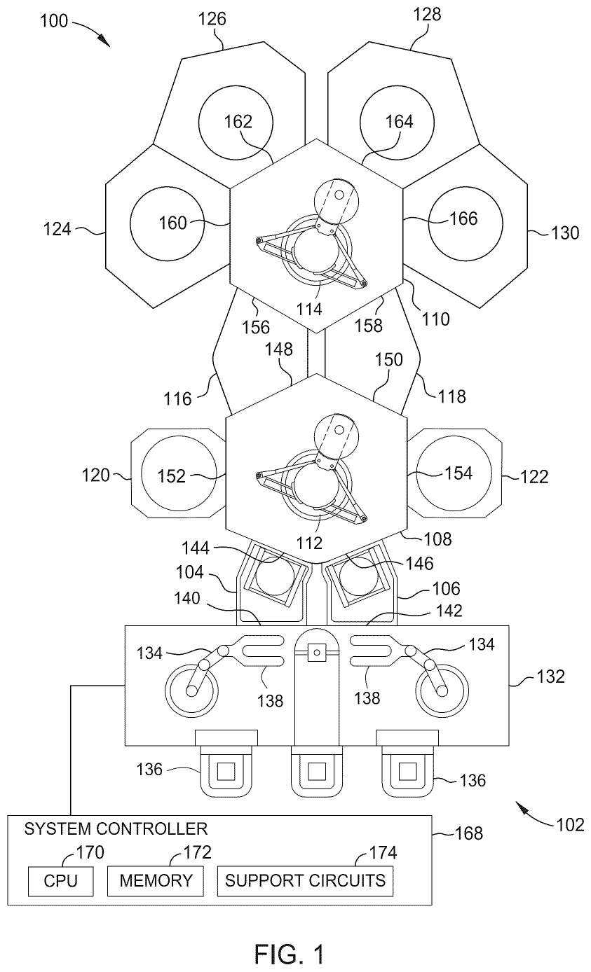

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152,154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

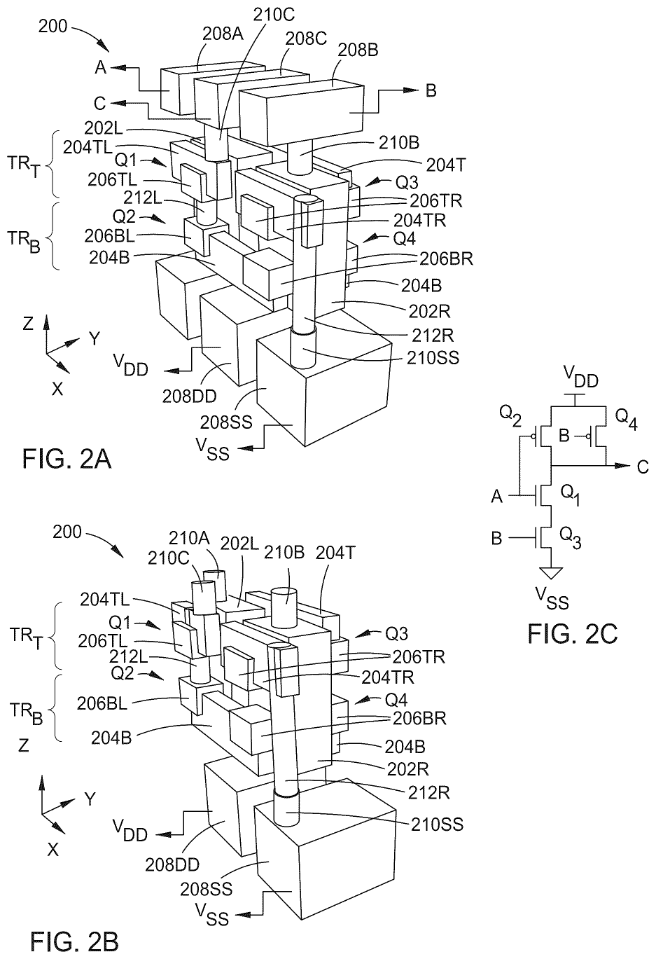

FIGS. 2A and 2B are isometric views of a portion of a semiconductor structure 200 that may form a complementary field-effect transistor (CFET) in a double-cell-height design, according to one or more embodiments of the present disclosure. In FIG. 2B, the semiconductor structure 200 beneath top metal layers is shown. FIG. 2C illustrates an exemplary NAND gate circuit that correspond to the portion of the semiconductor structures 200 shown in FIG. 2A.

The NAND gate circuit in FIG. 2C includes transistors Q₁, Q₂, Q₃, and Q₄. A first input terminal A is connected to the gate terminals of the transistors Q₁ and Q₂. A second input terminal B is connected to the gate terminals of the transistors Q₃ and Q₄. The transistors Q₁ and Q₃ are n-channel transistors and connected in series between a reference voltage V_{SS} (e.g., grounded) and an output terminal C. The transistors Q₂ and Q₄ are p-channel transistors and connected in parallel between the output terminal C and a power supply voltage V_{DD} (e.g., a positive voltage relative to the reference voltage V_{SS}). The output terminal C is connected to the drain terminals of transistors Q₁, Q₂, and Q₄.

The semiconductor structure 200 shown in FIGS. 2A and 2B includes a bottom field effect transistor (FET) module TR_{B}, and a top FET module TR_{T} stacked on the bottom FET module TR_{B} in the Z direction. In one example, the bottom FET module TR_{B} includes p-channel transistors Q₂ and Q₄, and the top FET module TR_{T} includes n-channel transistors Q₁ and Q₃. The transistor Q₁ is formed of a common metal gate 202L, a source/drain (S/D) contact 204TL electrically connected to one end of channel layers (not shown) extending through the common metal gate 202L in the Y direction via a S/D epitaxial (epi) region 206TL, and a common S/D contact 204T electrically connected to the other end of the channel layers via another S/D epi region 206TL. The transistor Q₂ is formed of the common metal gate 202L and common S/D contacts 204B each electrically connected to one end of channel layers (not shown) extending through the common metal gate 202L in the Y direction via a S/D epi region 206BL. The transistor Q₃ is formed of a common metal gate 202R, a S/D contact 204TR electrically connected to one end of channel layers (not shown) extending through the common metal gate 202R in the Y direction via a S/D epi region 206TR, and the common S/D contact 204T electrically connected to the other end of the channel layers via another S/D epi region 206TR. The transistor Q₄ is formed of the common metal gate 202R and the common S/D contacts 204B each electrically connected to one end of channel layers (not shown) extending through the common metal gate 202R in the Y direction via a S/D epi region 206BR. The S/D epi regions 206BL and 206BR in the bottom FET module TR_{B} may be doped with p-type dopants such as boron (B) or gallium (Ga), with a concentration of between about 10²⁰ cm⁻³ and 5×·10²¹ cm⁻³, depending upon the desired conductive characteristic of the S/D epi regions 206BL and 206BR. The S/D epi regions 206TL and 206TR in the top FET module TR_{T} may be doped with n-type dopants, such as phosphorus (P), arsenic (As), or antimony (Sb), with a concentration of between about 10²⁰ cm⁻³ and 5 ×·10²¹ cm⁻³, depending upon the desired conductive characteristic of the S/D epi regions 206TL and 206TR. In some other embodiments, the S/D epi regions 206BL and 206BR in the bottom FET module TR_{B} may be doped with n-type dopants, and the S/D epi regions 206TL and 206TR in the top FET module TR_{T} may be doped with p-type dopants.

The common metal gate 202L of the transistors Q₁ and Q₂ is electrically connected to a metal layer 208A (not shown in FIG. 2B) that is disposed on the top FET module TR_{T} in the Z direction and electrically connected to a first input terminal A via a contact plug 210A (shown in FIG. 2B). The common metal gate 202R of the transistors Q₃ and Q₄ is electrically connected to a metal layer 208B (not shown in FIG. 2B) that is disposed on the top FET module TR_{T} in the Z direction and electrically connected to a second input terminal B via a contact plug 210B. The drain contact 204TL of the transistor Q₁ and the common drain contact 204B of the transistors Q₂ and Q₄ are connected to a metal layer 208C (not shown in FIG. 2B) that is disposed on the top FET module TR_{T} in the Z direction and electrically connected to an output terminal C via a contact plug 210C and a via contact 212L. The common drain contact 204B of the transistors Q₂ and Q₄ are connected to a metal layer 208DD (not shown in FIG. 2B) that is disposed beneath the bottom FET module TR_{B} in the Z direction and electrically connected to a power supply voltage V_{DD} (e.g., a positive voltage relative to the reference voltage V_{SS}) via a contact plug (not shown). The source contact 204TR of the transistor Q₃ is electrically connected to a metal layer 208SS that is disposed beneath the bottom FET module TR_{B} in the Z direction and electrically connected to a reference voltage V_{SS} (e.g., grounded) via a contact plug 210SS and a via contact 212R.

The common metal gates 202L and 202R, the S/D contacts 204TL and 204TR, the common S/D contacts 204T and 204B, the metal layers 208A, 208B, 208C, 208DD, and 208SS, the contact plugs 210A, 210B, 210C, and 210SS, and the via contacts 212L and 212R may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof. The S/D epi regions 206TL, 206BL, 206TR, and 206BR may be formed of epitaxially grown silicon (Si) or silicon germanium (SiGe). The channel layers (not shown) extending through the common metal gates 202L and 202R may be formed of silicon (Si), germanium (Ge), silicon germanium (SiGe), or indium gallium zinc oxide (IGZO).

Surfaces of the common metal gates 202L and 202R along the ZX plane are covered by spacers (not shown) formed of dielectric material, such as silicon oxycarbide (SiOₓC_{y}). The S/D contacts 204TL and 204TR, the common S/D contacts 204T and 204B, the S/D epi regions 206TL, 206BL, 206TR, and 206BR, and the via contacts 212L and 212R are embedded within an inter-layer dielectric (ILD) (not shown) formed of silicon oxide (SiO₂), silicon oxynitride (SiON), aluminum oxide (Al₂O₃), or any combination thereof. The contact plugs 210A, 210B that are encapsulated within dielectric layers (not shown) formed of silicon oxide (SiO₂), silicon nitride (Si₃N₄), aluminum oxide (Al₂O₃), or any combination thereof that is carbon doped, such as silicon oxycarbide (SiOC), silicon oxycarbonitride (SiOCN), or silicon carbon nitride (SiCN).

In the double-cell-height design shown in FIGS. 2A and 2B, the transistors Q₁ and Q₃ are connected by the common S/D contact 204T, and the transistors Q₂ and Q₄ are connected via the common S/D contacts 204B, and thus routing through a metal layer, which would be required in a single-cell-height design, is not needed. Thus, routing requirement in the metal layer is relaxed in the double-cell-height design.

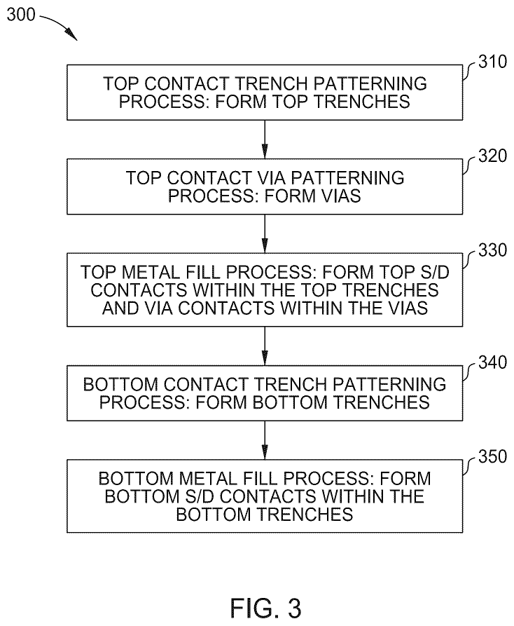

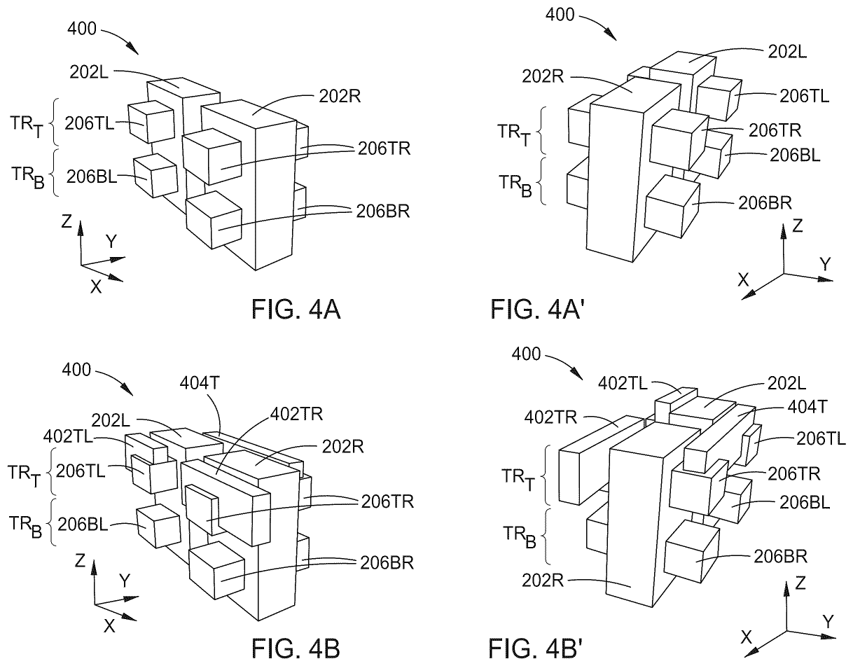

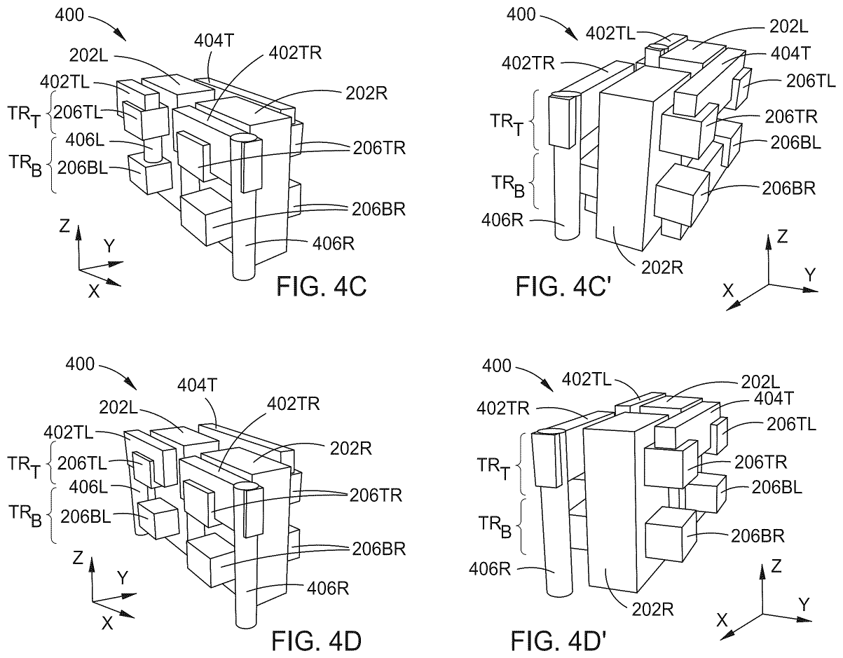

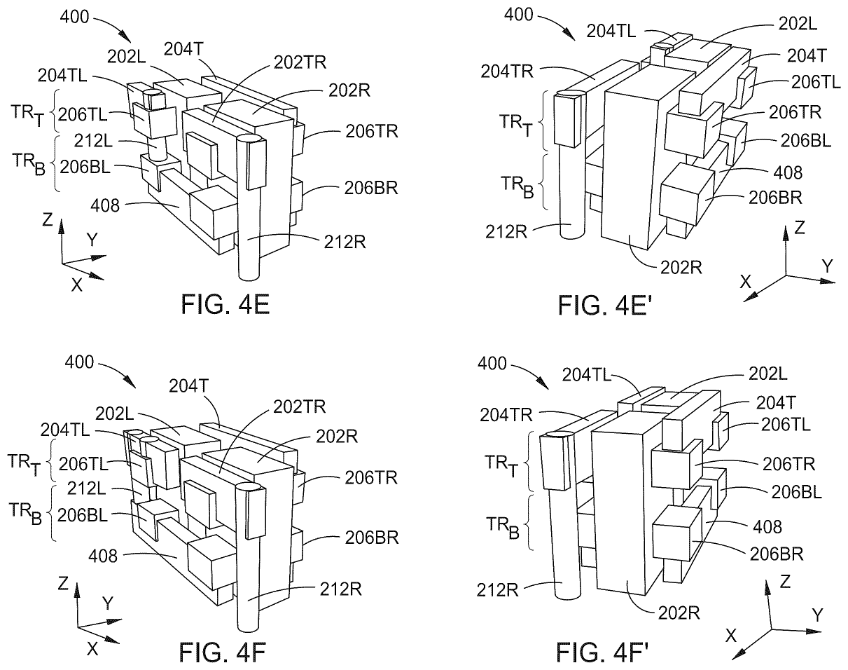

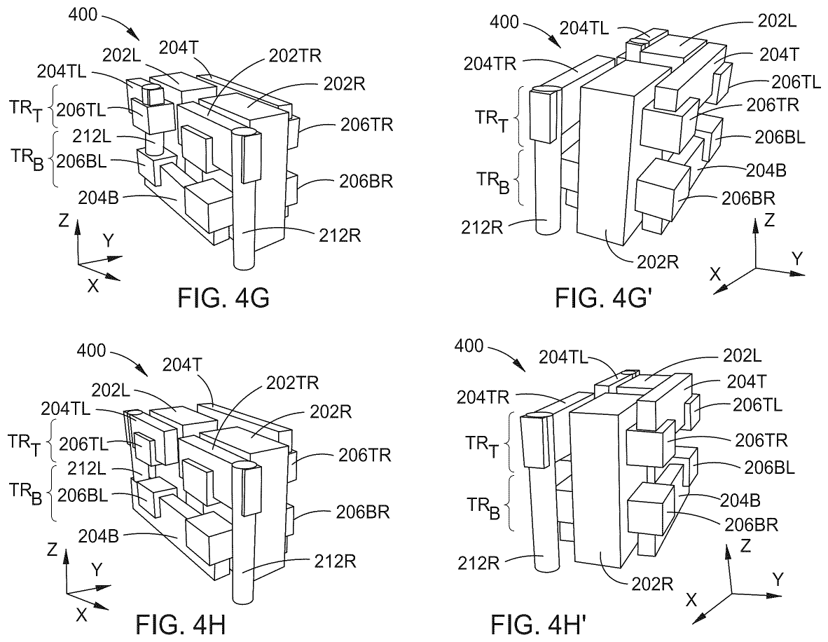

FIG. 3 depicts a process flow diagram of a method 300 of forming a semiconductor structure 400 that may be the semiconductor structure 200 forming a portion of a complementary field-effect transistor (CFET), according to one or more embodiments of the present disclosure. FIGS. 4A, 4A′, 4B, 4B′, 4C, 4C′, 4D, 4D′, 4E, 4E′, 4F, 4F′, 4G, 4G′, 4H, and 4H′ are isometric views of a portion of the semiconductor structure 400 corresponding to various states of the method 300. It should be understood that FIGS. 4A, 4A′, 4B, 4B′, 4C, 4C′, 4D, 4D′, 4E, 4E′, 4F, 4F′, 4G, 4G′, 4H, and 4H′ illustrate only partial schematic views of the semiconductor structure 400, and the semiconductor structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein.

As shown in FIGS. 4A and 4A′, the semiconductor structure 400 includes common metal gates 202L and 202R extending along the ZX plane, S/D epi regions 206TL at front and back sides of channel layers (not shown) extending through the common metal gate 202L in the Y direction, S/D epi regions 206BL at front and back sides of channel layers (not shown) extending through the common metal gate 202L in the Y direction, S/D epi regions 206TR at front and back sides of channel layers (not shown) extending through the common metal gate 202R in the Y direction, and S/D epi regions 206BR at front and back sides of channel layers (not shown) extending through the common metal gate 202R in the Y direction. The S/D epi regions 206TL, 206BL, 206TR, and 206BR on the front side of the common metal gates 202L and 202R are fully shown in FIG. 4A. The S/D epi regions 206TL, 206BL, 206TR, and 206BR on the back side of the common metal gates 202L and 202R are fully shown in FIG. 4A′. A bottom portion of the semiconductor structure 400 including the S/D epi regions 206BL and 206BR forms a bottom field effect transistor (FET) module TR_{B}, and a top portion of the semiconductor structure 400 including the S/D epi regions 206TL and 206TR forms a top FET module TR_{T} stacked on the bottom FET module TR_{B} in the Z direction.

The common metal gates 202L and 202R may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof. The S/D epi regions 206TL, 206BL, 206TR, and 206BR may be formed of epitaxially grown silicon (Si) or silicon germanium (SiGe). The S/D epi regions 206BL and 206BR in the bottom FET module TR_{B} may be doped with n-type dopants, such as phosphorus (P), arsenic (As), or antimony (Sb), with a concentration of between about 10²⁰ cm⁻³ and 5×·10²¹ cm⁻³, depending upon the desired conductive characteristic of the S/D epi regions 206BL and 206BR. The S/D epi regions 206TL and 206TR in the top FET module TR_{T} may be doped with p-type dopants such as boron (B) or gallium (Ga), with a concentration of between about 10²⁰ cm⁻³ and 5×·10²¹ cm⁻³, depending upon the desired conductive characteristic of the S/D epi regions 206TL and 206TR. In some other embodiments, the S/D epi regions 206BL and 206BR in the bottom FET module TR_{B} may be doped with p-type dopants, and the S/D epi regions 206TL and 206TR in the top FET module TR_{T} may be doped with n-type dopants.

The channel layers (not shown) extending through the common metal gates 202L and 202R may be formed of silicon (Si), germanium (Ge), silicon germanium (SiGe), or indium gallium zinc oxide (IGZO).

Surfaces of the common metal gates 202L and 202R along the ZX plane are covered by spacers (not shown) formed of dielectric material, such as silicon oxycarbide (SiOₓC_{y}) and silicon nitride (Si₃N₄). The S/D epi regions 206TL, 206BL, 206TR, and 206BR are embedded within an inter-layer dielectric (ILD) (not shown) formed silicon oxide (SiO₂), silicon oxynitride (SiON), aluminum oxide (Al₂O₃), or any combination thereof.

The method 300 begins with block 310, in which a top contact trench patterning process is performed to form trenches 402TL, 402TR, and 404T, as shown in FIGS. 4B and 4B′. The trenches 402TL, 402TR, and 404T are formed by etching into the S/D epi regions 206TL and 206TR and the ILD (not shown) adjacent to the S/D epi region 206TL and 206TR from a top side of the semiconductor structure 400. The top contact trench patterning process may include any appropriate lithography and etch processes, such as photolithography and a reactive ion etching (RIE) performed in a processing chamber, such as the processing chamber 120 shown in FIG. 1, and any appropriate deposition process, such as such as chemical vapor deposition (CVD), physical vapor deposition (PVD), or the like performed in a processing chamber, such as the processing chamber 126, 128, or 130 shown in FIG. 1.

In block 320, a top contact via patterning process is performed to form vias 406L and 406R, as shown in FIGS. 4C and 4C′. The via 406L is formed by etching through the S/D epi region 206TL and the MDI (not shown) between the S/D epi regions 206TL and 206BL from the top side of the semiconductor structure 400 into the S/D epi region 206BL. The via 406R is formed by etching through the ILD (not shown) adjacent to the S/D epi regions 206TR and 206BR from the top side of the semiconductor structure 400. Thus, an area to form the via 406R is reduced as compared to alternative embodiments, in which the via 406L is formed by etching through the ILD (not shown) adjacent to the S/D epi regions 206TL and 206BL (not through the S/D epi region 206TL or into the S/D epi region 206BL) as shown in FIGS. 4D and 4D′. However, in the alternative embodiments, the etch process is only through the ILD, and thus a damage to the S/D epi region 206TL or the S/D epi region 206BL can be avoided during the etch process.

The top contact via patterning process may include any appropriate lithography and etch processes, such as photolithography and a reactive ion etching (RIE) performed in a processing chamber, such as the processing chamber 120 shown in FIG. 1, and any appropriate deposition process, such as such as chemical vapor deposition (CVD), physical vapor deposition (PVD), or the like performed in a processing chamber, such as the processing chamber 126, 128, or 130 shown in FIG. 1.

In block 330, a top metal fill process is performed to form the S/D contact 204TL within the trench 402TL, the S/D contact 204TR within the trench 402TR, and the common S/D contact 204T within the trench 404T, a via contact 212L within the via 406L, and a via contact 212R within the via 406R as shown in FIGS. 4E and 4E′ or FIGS. 4F and 4F′. The top metal fill process may include forming a metal silicide at interfaces with the S/D epi regions 206TL, 206BL, and 206TR within the trenches 402TL, 402TR, and 404T and the vias 406L and 406R, and filling the trenches 402TL, 402TR, and 404T and the vias 406L and 406R with metal fill material. The metal silicide may be titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof. The metal fill material may be tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

The top metal fill process may include any appropriate deposition process, such as such as chemical vapor deposition (CVD), physical vapor deposition (PVD), or the like performed in a processing chamber, such as the processing chamber 126, 128, or 130 shown in FIG. 1.

In block 340, a bottom contact trench patterning process is performed to form trenches 408, as shown in FIGS. 4E and 4E′ or in FIGS. 4F and 4F′. The trenches 408 are formed by etching into the S/D epi regions 206BL and 206BR and the ILD (not shown) adjacent to the S/D epi region 206BL and 206BR from a bottom side of the semiconductor structure 400. The bottom contact trench patterning process may include any appropriate lithography and etch processes, such as photolithography and a reactive ion etching (RIE) performed in a processing chamber, such as the processing chamber 120 shown in FIG. 1, and any appropriate deposition process, such as such as chemical vapor deposition (CVD), physical vapor deposition (PVD), or the like performed in a processing chamber, such as the processing chamber 126, 128, or 130 shown in FIG. 1.

In block 350, a bottom metal fill process is performed to form the common S/D contacts 204B within the trenches 408 as shown in FIGS. 4G and 4G′ or 4H or 4H′. The bottom metal fill process may include forming a metal silicide at interfaces with the S/D epi regions 206BL and 206BR within the trenches 408 formed, and filling the trenches 408 with metal fill material to form the common S/D contacts 204B. The metal silicide may be titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof. The metal fill material may be tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

The bottom metal fill process may include any appropriate deposition process, such as such as chemical vapor deposition (CVD), physical vapor deposition (PVD), or the like performed in a processing chamber, such as the processing chamber 126, 128, or 130 shown in FIG. 1.

The embodiments described herein provide methods for complementary FET (CFET) devices. In the methods described herein, a dummy contact is deposited in place for a bottom source/drain (S/D) contact for a bottom FET module of a CFET before high temperature process, such epitaxial deposition processes and a replacement metal gate process, and subsequently replaced with a bottom S/D contact formed of metal. This replacement S/D contact allows the use of most optimized materials for a bottom S/D contact in the bottom FET module without any thermal budget constraints.

In the double-cell-height structures of complementary FET (CFET) devices according to the embodiments described herein, two row of stacks of an n-FET and a p-FET are interconnected by common S/D contacts and controlled by two common gates. Due to the internal connections among FET devices, routing through a metal layer over the FET devices is reduced and routing complexity of a CFET device is minimized. Further, the interconnect length, without the routing through a metal layer, is shortened and thus parasitic resistance of a CFET device is reduced.

While the foregoing is directed to embodiments of the present disclosure, other and further embodiments of the disclosure may be devised without departing from the basic scope thereof, and the scope thereof is determined by the claims that follow.

1. A semiconductor structure forming a complementary field-effect transistor (CFET), comprising:
a first common metal gate;
a second common metal gate;
a bottom field effect transistor (FET) module, the bottom FET module comprising:
a pair of bottom common source/drain (S/D) contacts electrically connected to each other through the first common metal gate in a first direction via first bottom S/D epitaxial (epi) regions, and through the second common metal gate in the first direction via second bottom S/D epi regions; and
a top FET module stacked on the bottom FET module in a second direction that is orthogonal to the first direction, the top FET module comprising:
a top common S/D contact;
a first top S/D contact electrically connected to the top common S/D contact through the first common metal gate in the first direction via first top S/D epi regions; and
a second top S/D contact electrically connected to the top common S/D contact through the second common metal gate in the first direction via second top S/D epi regions.

2. The semiconductor structure of claim 1, wherein
the first bottom S/D epi regions and the second bottom S/D epi regions are epitaxially grown silicon (Si) or silicon germanium (SiGe) doped with p-type dopants, and
the first top S/D epi regions and the second top S/D epi regions are epitaxially grown silicon (Si) or silicon germanium (SiGe) doped with n-type dopants.

3. The semiconductor structure of claim 1, wherein
the first bottom S/D epi regions and the second bottom S/D epi regions are epitaxially grown silicon (Si) or silicon germanium (SiGe) doped with n-type dopants, and
the first top S/D epi regions and the second top S/D epi regions are epitaxially grown silicon (Si) or silicon germanium (SiGe) doped with p-type dopants.

4. The semiconductor structure of claim 1, further comprising:
a via contact electrically connecting the first top S/D contact to one of the pair of bottom common S/D contacts.

5. The semiconductor structure of claim 4, wherein the via contact is formed through the first top S/D epi region connected to the first top S/D contact and into the first bottom S/D epi region connected to the one of the pair of the bottom common S/D contacts.

6. The semiconductor structure of claim 5, further comprising:
a first bottom metal layer and a second bottom metal layer beneath the bottom FET module in the second direction, wherein
the other of the pair of bottom common S/D contacts is electrically connected to the first bottom metal layer, and
the second top S/D contact is electrically connected to the second bottom metal layer.

7. The semiconductor structure of claim 1, further comprising:
a first top metal layer, a second top metal layer, and a third top metal layer on the top FET module in the second direction, wherein
the first top metal layer is electrically connected to the first common metal gate,
the second top metal layer is electrically connected to the second common metal gate, and
the third top metal layer is electrically connected to the first top S/D contact.

8. The semiconductor structure of claim 1, wherein the first common metal gate and the second common metal gate each comprise tungsten (W), ruthenium (Ru), or molybdenum (Mo).

9. A method of forming a complementary field-effect transistor (CFET), comprising:
performing a top contact trench patterning process to form a first top trench into a first front top S/D epi region, a second top trench into a second front top S/D epi region, and a third top trench into a first back top S/D epi region and a second back top S/D epi region, wherein
the first front top S/D epi region and the first back top S/D epi region are electrically connected through a first common metal gate, and
the second front top S/D epi region and the second back top S/D epi region are electrically connected through a second common metal gate;
performing a top contact via patterning process to form a first via through the first front top S/D epi region and into a first front bottom S/D epi region, and a second via adjacent to the second front top S/D epi region and a second front bottom S/D epi region, wherein
the first front bottom S/D epi region and a first back bottom S/D epi region are electrically connected through the first common metal gate, and
the second front bottom S/D epi region and a second back bottom S/D epi region are electrically connected through the second common metal gate;
performing a top metal fill process to form a first top S/D contact within the first top trench, a second top S/D contact within the second top trench, a top common S/D contact within the third top trench, a first via contact within the first via, and a second via contact within the second via;
performing a bottom contact trench patterning process to form a first bottom trench into the first bottom front S/D epi region and the second bottom front S/D epi region and a second bottom trench into the first bottom back S/D epi region and the second bottom back S/D epi region; and
performing a bottom metal fill process, to form a common bottom S/D contact within each of the first bottom trench and the second bottom trench.

10. The method of claim 9, wherein the first common metal gate and the second common metal gate each comprise tungsten (W), ruthenium (Ru), or molybdenum (Mo).

11. The method of claim 9, wherein
the first front top S/D epi region, the second front top S/D epi region, the first back top S/D epi region, and the second back top S/D epi region are epitaxially grown silicon (Si) or silicon germanium (SiGe) doped with n-type dopants, and
the first front bottom S/D epi region, the second front bottom S/D epi region, the first back bottom S/D epi region, and the second back bottom S/D epi region are epitaxially grown silicon (Si) or silicon germanium (SiGe) doped with p-type dopants.

12. The method of claim 9, wherein
the first front top S/D epi region, the second front top S/D epi region, the first back top S/D epi region, and the second back top S/D epi region are epitaxially grown silicon (Si) or silicon germanium (SiGe) doped with p-type dopants, and
the first front bottom S/D epi region, the second front bottom S/D epi region, the first back bottom S/D epi region, and the second back bottom S/D epi region are epitaxially grown silicon (Si) or silicon germanium (SiGe) doped with n-type dopants.

13. The method of claim 9, wherein
the top metal fill process comprises:
forming metal silicide at interfaces with the first front top S/D epi region within the first top trench, at interfaces with the second front top S/D epi region within the second top trench, at interfaces with the first back top S/D epi region and the second back top S/D epi region within the third top trench, at interfaces with the first front top S/D epi region and the first front bottom S/D epi region within the first via; and
filling the first top trench, the second top trench, the third top trench, the first via, and the second via with metal fill material, and
the bottom metal fill process comprises:
forming metal silicide at interfaces with the first bottom front S/D epi region and the second bottom front S/D epi region within the first bottom trench and at interfaces with the first bottom back S/D epi region and the second bottom back S/D epi region within the second bottom trench; and
filling the first bottom trench and the second bottom trench with metal fill material.

14. The method of claim 13, wherein the metal silicide comprises titanium silicide, nickel silicide, or molybdenum silicide and the metal fill material comprises tungsten (W), ruthenium (Ru), or molybdenum (Mo).

15. A method of forming a complementary field-effect transistor (CFET), comprising:
performing a top contact trench patterning process to form a first top trench into a first front top S/D epi region, a second top trench into a second front top S/D epi region, and a third top trench into a first back top S/D epi region and a second back top S/D epi region, wherein
the first front top S/D epi region and the first back top S/D epi region are electrically connected through a first common metal gate, and
the second front top S/D epi region and the second back top S/D epi region are electrically connected through a second common metal gate;
performing a top contact via patterning process to form a first via adjacent to the first front top S/D epi region and a first front bottom S/D epi region, and a second via adjacent to the second front top S/D epi region and a second front bottom S/D epi region, wherein
the first front bottom S/D epi region and a first back bottom S/D epi region are electrically connected through the first common metal gate, and
the second front bottom S/D epi region and a second back bottom S/D epi region are electrically connected through the second common metal gate;
performing a top metal fill process to form a first top S/D contact within the first top trench, a second top S/D contact within the second top trench, a top common S/D contact within the third top trench, a first via contact within the first via, and a second via contact within the second via;
performing a bottom contact trench patterning process to form a first bottom trench into the first bottom front S/D epi region and the second bottom front S/D epi region and a second bottom trench into the first bottom back S/D epi region and the second bottom back S/D epi region; and
performing a bottom metal fill process, to form a common bottom S/D contact within each of the first bottom trench and the second bottom trench.

16. The method of claim 15, wherein the first common metal gate and the second common metal gate each comprise tungsten (W), ruthenium (Ru), or molybdenum (Mo).

17. The method of claim 15, wherein
the first front top S/D epi region, the second front top S/D epi region, the first back top S/D epi region, and the second back top S/D epi region are epitaxially grown silicon (Si) or silicon germanium (SiGe) doped with n-type dopants, and
the first front bottom S/D epi region, the second front bottom S/D epi region, the first back bottom S/D epi region, and the second back bottom S/D epi region are epitaxially grown silicon (Si) or silicon germanium (SiGe) doped with p-type dopants.

18. The method of claim 15, wherein
the first front top S/D epi region, the second front top S/D epi region, the first back top S/D epi region, and the second back top S/D epi region are epitaxially grown silicon (Si) or silicon germanium (SiGe) doped with p-type dopants, and
the first front bottom S/D epi region, the second front bottom S/D epi region, the first back bottom S/D epi region, and the second back bottom S/D epi region are epitaxially grown silicon (Si) or silicon germanium (SiGe) doped with n-type dopants.

19. The method of claim 15, wherein
the top metal fill process comprises:
forming metal silicide at interfaces with the first front top S/D epi region within the first top trench, at interfaces with the second front top S/D epi region within the second top trench, at interfaces with the first back top S/D epi region and the second back top S/D epi region within the third top trench, at interfaces with the first front top S/D epi region and the first front bottom S/D epi region within the first via; and
filling the first top trench, the second top trench, the third top trench, the first via, and the second via with metal fill material, and
the bottom metal fill process comprises:
forming metal silicide at interfaces with the first bottom front S/D epi region and the second bottom front S/D epi region within the first bottom trench and at interfaces with the first bottom back S/D epi region and the second bottom back S/D epi region within the second bottom trench; and
filling the first bottom trench and the second bottom trench with metal fill material.

20. The method of claim 19, wherein the metal silicide comprises titanium silicide, nickel silicide, or molybdenum silicide and the metal fill material comprises tungsten (W), ruthenium (Ru), or molybdenum (Mo).
